(19) United States
(12) Patent Application Publication
(10) Pub. No.: US 2024/0393372 A1
(43) Pub. Date: Nov. 28, 2024

(54) COMMON MODE FIELD REJECTION MAGNETIC CURRENT SENSOR

(71) Applicant: Allegro MicroSystems, LLC, Manchester, NH (US)

(72) Inventors: Anuraag Mohan, Fremont, CA (US); Zack Deiri, Danville, CA (US)

(73) Assignee: Allegro MicroSystems, LLC, Manchester, NH (US)

(21) Appl. No.: 18/691,998

(22) PCT Filed: Oct. 10, 2022
(86) PCT No.: PCT/IB2022/059686

§ 371 Date: Mar. 14, 2024

Related U.S. Application Data
(60) Provisional application No. 63/275,607, filed on Nov. 4, 2021.

(51) Int. Cl. G01R 15/20; G01R 19/00

(52) U.S. Cl. CPC G01R 15/205; G01R 19/0092

(57) ABSTRACT

The present disclosure concerns a current measurement system, comprising an electrically conductive strip (10) extending along a first direction (y) and comprises a notch (51) extending substantially perpendicular to the first direction (y). A first and second magnetic sensors (21, 22) are provided respectively on each side of the notch (51) and are configured to output a first output signal (V_{out,1}) according to a first signal magnetic field (41) and a second output signal (V_{out,2}), respectively. An output signal (Vₒᵤₜ) corresponds to the difference between the first and the second output signals (V_{out,1}. V_{out,2}). The current measurement system enables current sensing in 100s-1000s A accurately.

### TECHNICAL DOMAIN

The present disclosure concerns a magnetic current sensor. More particularly, the present disclosure concerns a differential magnetic current sensor. The magnetic current sensor is insensitive to the presence of an external uniform magnetic field.

### RELATED ART

Most precision current sensors rely on packaging structures and techniques for current sensor integrated circuits (IC) or discrete magnetic modules with magnetic cores (or shields) to cancel the interference due to ambient magnetic fields. Both these solutions have serious application limitations. The current sensor ICs are limited by the amount of current that can be passed through the sensor. The magnetic modules are very bulky and expensive to develop and manufacture.

### SUMMARY

The present disclosure concerns a current measurement system, comprising an electrically conductive strip extending along a first direction and configured to pass a signal current to be measured along the first direction. The current measurement system further comprises a first magnetic sensor and a second magnetic sensor, wherein each magnetic sensor is configured to output an output signal according to a signal magnetic field that is generated by the signal current. The strip comprises a first notch, extending from a first lateral side of the strip, along a second direction substantially perpendicular to the first direction and forming a first edge and a second edge on each side of the first notch along the second direction. In a first zone of the strip bordering the first edge, the signal current comprises a first current portion flowing substantially in the second direction and generates a first signal magnetic field with a first polarity. In a second zone of the strip bordering the second edge, the signal current comprises a second current portion flowing substantially in the second direction and generating a second signal magnetic field with a second polarity opposed to the first polarity. The first magnetic sensor is arranged in the first zone to outputs a first output signal according to the first signal magnetic field, and the second magnetic sensor is arranged in the second zone to outputs a second output signal according to the second signal magnetic field, the output signal corresponding to the difference between the first and the second output signals.

The current measurement system is common mode field rejection measurement system since it allows for cancelling interference due to an external uniform external magnetic field. The current measurement system has a much smaller form-factor compared to the existing modules and systems that rely on magnetic shields. The current measurement system enables current sensing in 100s-1000s A accurately.

### SHORT DESCRIPTION OF THE DRAWINGS

Exemplar embodiments of the invention are disclosed in the description and illustrated by the drawings in which:

FIG. 1 illustrates a perspective view of a current measurement system comprising an electrically conductive busbar and a first and second magnetic sensors, according to an embodiment;

FIG. 2 shows a top view of the current measurement system without the magnetic sensors, according to an embodiment;

FIG. 3 shows a top view of the current measurement system with the magnetic sensors, according to an embodiment;

FIG. 4 represents an example of a TMR element;

FIG. 5 illustrates a first and second magnetic sensors, each comprising a TMR element;

FIG. 6 shows a top view of the current measurement system without the magnetic sensors, according to another embodiment;

FIG. 7 shows a top view of the current measurement system with the magnetic sensors, according to the other embodiment;

FIG. 8 reports the measured output signal as a function of the signal current passed in the busbar with the current measurement system;

FIG. 9 reports the measured output signal as a function of the signal magnetic field; and

FIG. 10 shows an example of the current measurement system implemented on a PCB.

### EXAMPLES OF EMBODIMENTS

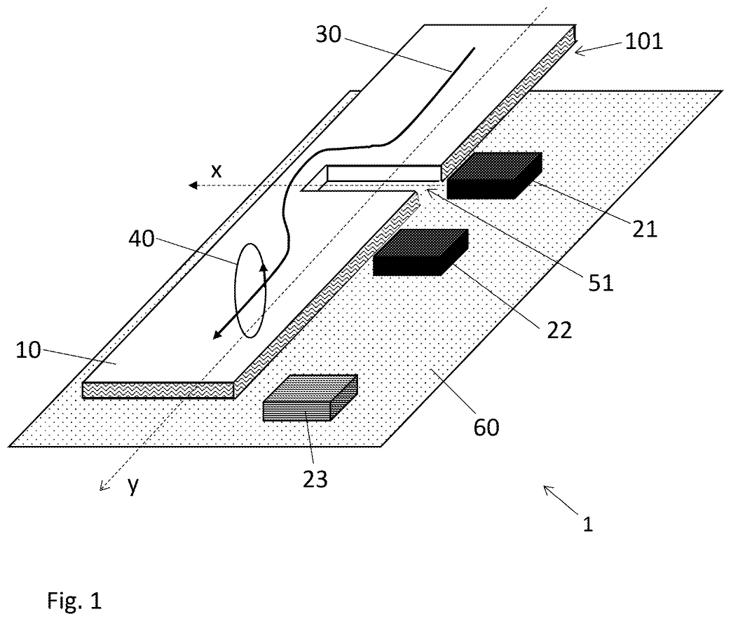

FIG. 1 illustrates a perspective view of a current measurement system 1 according to an embodiment. The current measurement system 1 comprises an electrically conductive busbar 10 extending along a first direction indicated by the axis y in FIG. 1. The busbar 10 is configured to pass a signal current 30 to be measured along the first direction y.

The current measurement system 1 further comprises at least two magnetic sensors. In the configuration shown in FIG. 1, the current measurement system 1 comprises a first magnetic sensor 21 and a second magnetic sensor 22. Each magnetic sensor 21, 22 is configured to output an output signal according to a signal magnetic field 40 that is generated by the signal current 30.

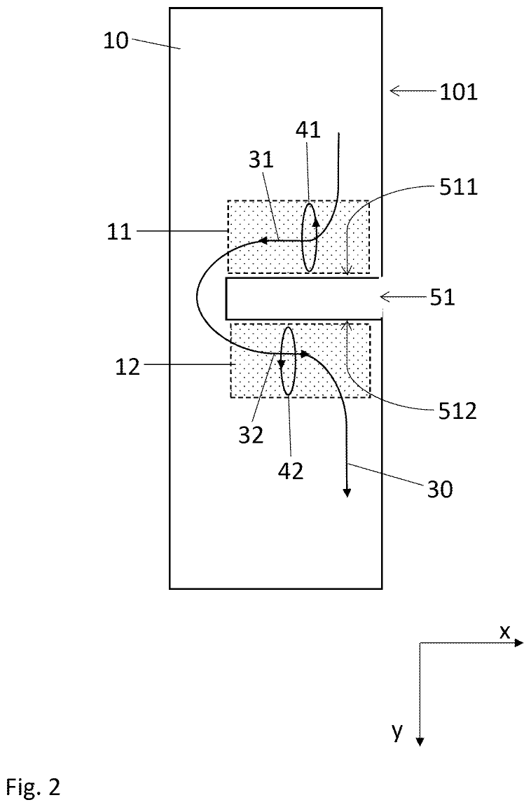

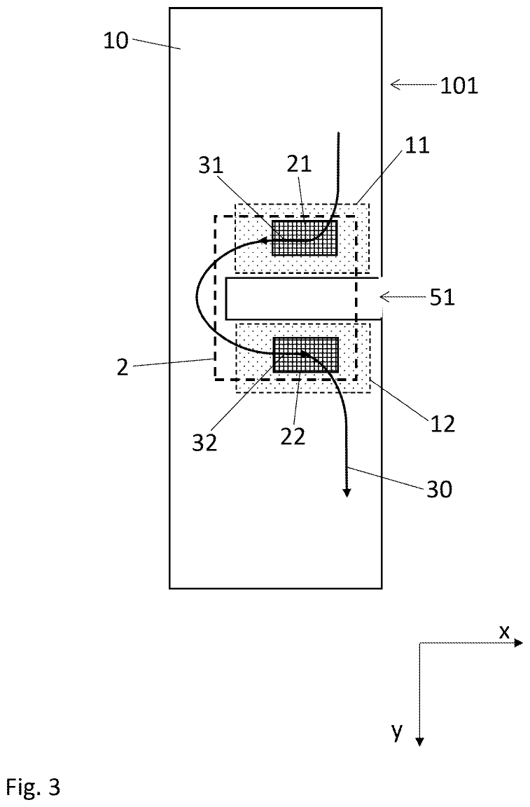

FIGS. 2 and 3 shows a top view of the current measurement system 1 without the magnetic sensor 21, 22 (FIG. 2) and showing the magnetic sensor 21, 22 (FIG. 3).

The busbar 10 comprises a first notch 51, extending from a first lateral side 101 of the busbar 10. The first notch 51 extends along a second direction x substantially perpendicular to the first direction y. In other words, the first notch 51 is a cut out in the busbar 10 performed in a direction substantially orthogonal to the busbar length. The notch 51 forms a first edge 511 and a second edge 512 on each side of the first notch 51 along the second direction x (see FIG. 2). In a first zone 11 of the busbar bordering (abutting) the first edge 11, the signal current 30 comprises a first current portion 31 that flows substantially along the first edge 511, thus substantially in the second direction x. In a second zone 12 of the busbar 10 bordering (abutting) the second edge 512, the signal current 30 comprises a second current portion 32 that flows substantially along the second edge 512, thus substantially in the second direction x, but having a polarity opposed to the one of the first current portion 31.

The configuration of the busbar 10 shown in FIGS. 1 to 3 provides a first current portion 31 generating a first signal magnetic field 41 having a first polarity and a second signal magnetic field 42 having a second polarity, opposed to the first polarity. The current measurement system 1 thus form a differential magnetic current sensor.

Advantageously, the first magnetic sensor 21 is arranged in the first zone 11 to outputs an output signal according to the first signal magnetic field 41. The second magnetic sensor 22 is arranged in the second zone 12 to outputs an output signal according to the second signal magnetic field 42. The first and second magnetic sensors 21, 22 can be configured such that a first output signal V_{out,1} outputted by the first magnetic sensor 21 when subjected to the first signal magnetic field 41 (generated by the first current portion 31) differs from the second output signal V_{out,2} outputted by the second magnetic sensor 22 subjected to the second signal magnetic field 42 (generated by the second current portion 32). The first and second magnetic sensors 21, 22 can be configured such that a first and a second output signal V_{out,1} and V_{out,2} outputted by the first and second magnetic sensor 21, 22, respectively, are equal when the first and second magnetic sensors 21, 22 are subjected by an external uniform magnetic field.

In one aspect, the current measurement system 1 is configured to output an output signal Vₒᵤₜ corresponding to the difference between the first and the second output signals V_{out,1}, V_{out,2}. The output signal Vₒᵤₜ is then proportional to an amplitude variation of the signal current 30.

The current measurement system 1 produces no measurable voltage output Vₒᵤₜ in the presence of an external uniform magnetic field. In other words, the differential of the first and the second output signals V_{out,1}, V_{out,2}, is insensitive to the presence of an external uniform magnetic field.

The current measurement system 1 can comprise a processing device 23 (see FIG. 1) configured to subtract the first output signal V_{out,1} outputted by the first magnetic sensor 21 and the second output signal V_{out,2} outputted by the second magnetic sensor 22.

In one aspect, each of the first and second magnetic sensors 21, 22 can comprise a tunnel magnetoresistive (TMR) element.

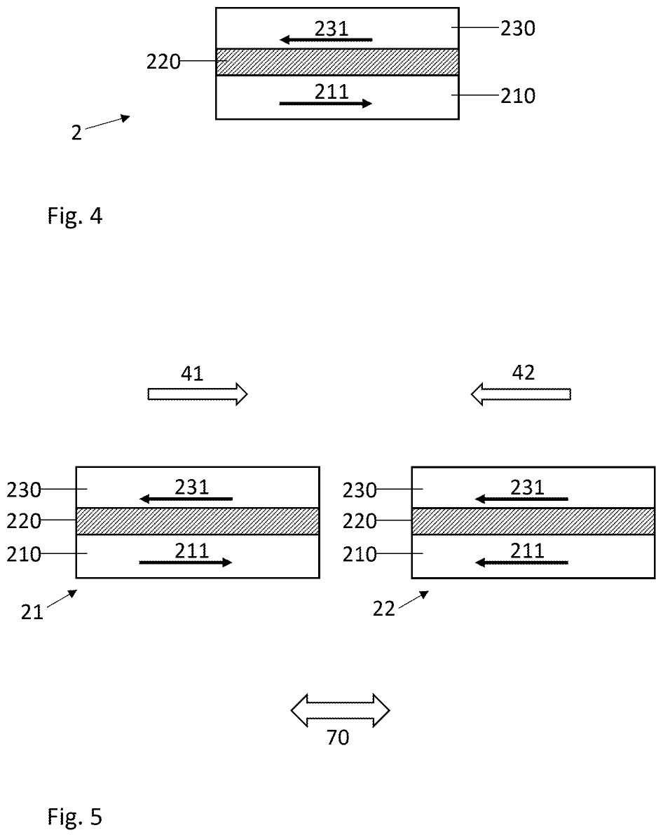

An example of such a TMR element 2 is represented in FIG. 4. Here, the TMR element 2 comprises a tunnel barrier layer 220 sandwiched between a ferromagnetic reference layer 230 having a pinned reference magnetization 231, and a ferromagnetic sense layer 210 having a sense magnetization 211 that can be freely oriented in a magnetic field.

FIG. 5 illustrates the first and second magnetic sensors 21, 22, each comprising a TMR element as described above. The first magnetic sensor 21 is measuring the first signal magnetic field 41 and the second magnetic sensor 22 is measuring the second signal magnetic field 42 which polarity is opposed to the one of the first signal magnetic field 41. The reference magnetization 231 of both magnetic sensors 21, 22 is pinned in the same direction. The sense magnetization 211 of the first magnetic sensor 21 is oriented antiparallel to the sense magnetization 211 of the second magnetic sensor 22, in accordance with the polarity of the first and second signal magnetic fields 41, 42. In this example, the sense magnetization 211 of the first magnetic sensor 21 is antiparallel to the reference magnetization 231 and the resistance of the first magnetic sensor 21 is high, corresponding to a high first output signal V_{out,1}. The sense magnetization 211 of the second magnetic sensor 22 is parallel to the reference magnetization 231 and the resistance of the second magnetic sensor 22 is low, corresponding to a low second output signal V_{out,2}. A voltage output Vₒᵤₜ corresponding to V_{out,1}-V_{out,2} is positive. By switching the polarity of the signal current 30 passing in the busbar 10, the relative orientations of the first and second signal magnetic fields 41, 42 are reversed and a voltage output Vₒᵤₜ corresponding to V_{out,1}-V_{out,2} is negative. An external uniform magnetic field 70 will orient the sense magnetization 211 of the first and second magnetic sensors 21, 22 in the same direction (the direction of the uniform magnetic field 70).

Consequently, the sense magnetization 211 of the first and second magnetic sensors 21, 22 will be oriented either parallel or antiparallel to the reference magnetization 231 and a voltage output Vₒᵤₜ corresponding to V_{out,1}-V_{out,2} is zero in both cases. The voltage output Vₒᵤₜ is thus insensitive to the external uniform magnetic field 70. The current measurement system 1 is a common mode field rejection current measurement system.

In one aspect not represented, each of the first and second magnetic sensors 21, 22 comprises four TMR elements arranged in a Wheatstone bridge circuit.

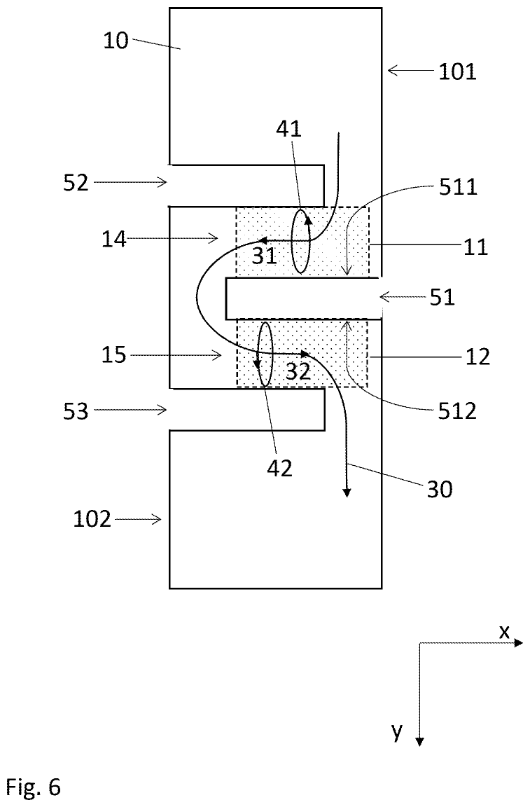

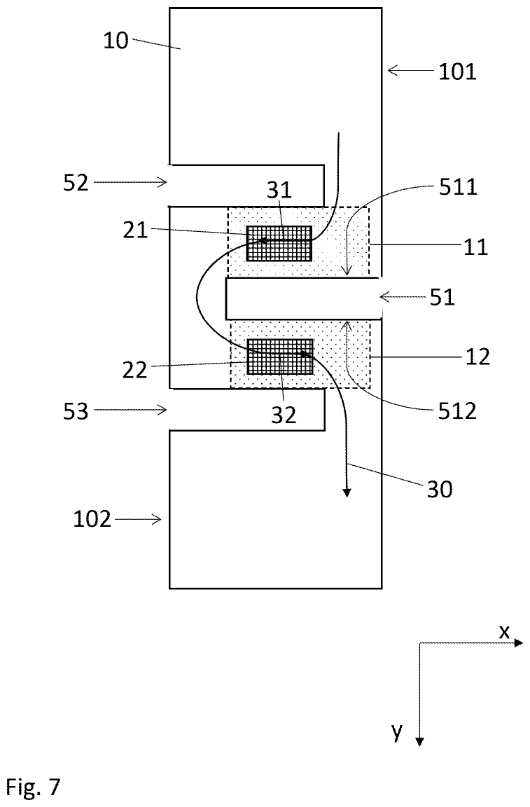

FIGS. 6 and 7 shows a top view of the current measurement system 1 without the magnetic sensor 21, 22 (FIG. 6) and showing the magnetic sensor 21, 22 (FIG. 7), according to another embodiment.

In the embodiment of FIGS. 6 and 7, the busbar 10 further comprises a second notch 52 and a third notch 53. The second and third notches 52, 53 extend from a second side 102 of the busbar 10, opposed to the first side 101. In this configuration, the first zone 11 comprises an electrically conductive first sub-strip 14 and the second zone 12 comprises an electrically conductive second sub-strip 15. Each of the first and second sub-strips 14, 15 extends on each side the first notch 51 along the first direction y. The first and second sub-strips 14, 15 advantageously extend substantially parallel to the first notch 51 (along the second direction x).

The width of the first and second sub-strips 14, 15 can be such as to increase current density of the first current portion 31 and the second current portion 32 and thus increase the magnitude of the first and second signal magnetic fields 41, 42.

The first and second magnetic sensors 21, 22 can be placed in the vicinity of the busbar 10. In particular, the first magnetic sensor 21 can be placed in the vicinity of the first zone 11, or first sub-strip 14, and the second magnetic sensor 22 can be placed in the vicinity of the second zone 12, or second sub-strip 15. The second magnetic sensors 21, 22 are not in contact with the busbar 10. The current measurement system 1 is thus a contactless current measurement system.

It should be noted that the current measurement system 1 can comprise any number of first magnetic sensors 21 located in the vicinity of the first zone 11 in order to measure the first current portion 32 (the first signal magnetic field 41) and output a first output signal V_{out,1}. Here, the first output signal V_{out,1} can correspond to the output signal of each first magnetic sensors 21, such as the sum of these outputs. The current measurement system 1 can also comprise any number of second magnetic sensors 22 located in the vicinity of the second zone 12 in order to measure the second current portion 32 (the second signal magnetic field 42) and output a second output signal V_{out,2}. Here, the second output signal V_{out,2} can correspond to the output signal of each second magnetic sensors 22, such as the sum of these outputs.

Referring back to FIG. 1, the magnetic sensors 21, 22 can be mounted on a PCB 60. The PCB containing the magnetic sensor 21, 22 can be placed in vicinity, below or above the busbar 10. The processing device 23 can be mounted on the PCB.

The busbar 10 can comprise any electrically conductive strip (or trace). The electrically conductive strip can be self-standing or formed on an substrate. The electrically conductive strip can comprise of be made of any electrically conductive material.

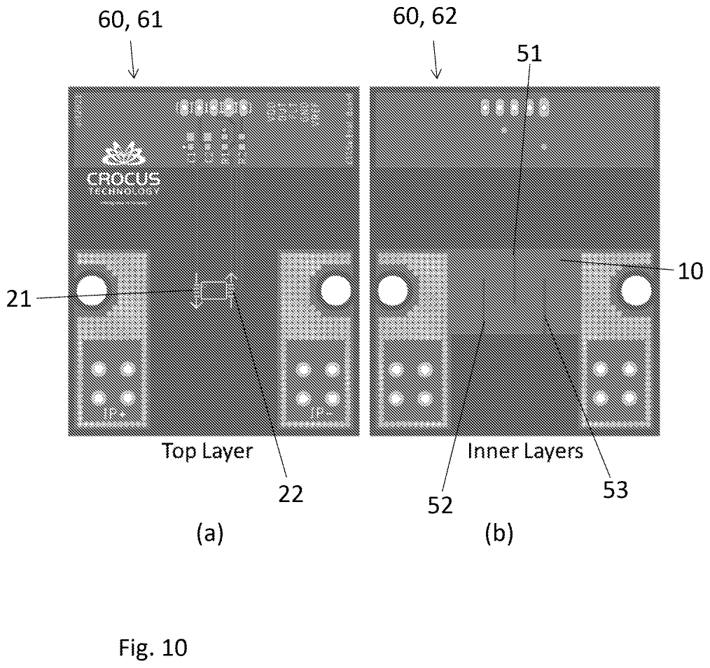

FIG. 10 shows an example of the current measurement system 1 implemented on a PCB 60, wherein a top PCB layer 61 comprises the first and second magnetic sensors 21, 22 and a an inner PCB layer 61 comprises the busbar 10.

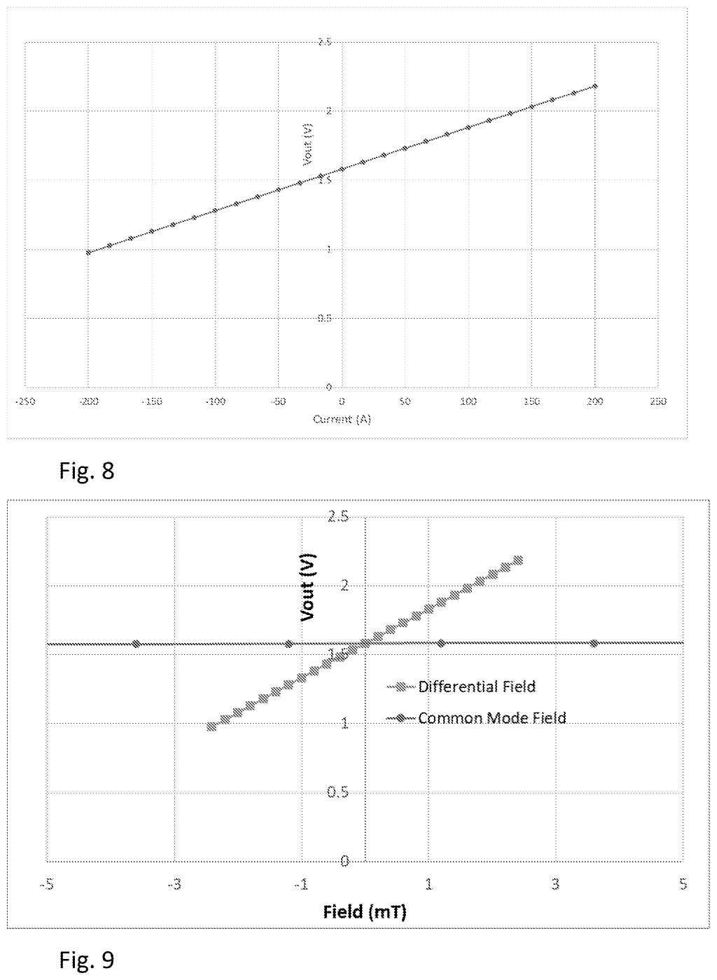

FIG. 8 reports the measured output signal Vₒᵤₜ as a function of the signal current 30 passed in the busbar 10 with the current measurement system 1 disclosed herein. FIG. 9 reports the measured output signal Vₒᵤₜ as a function of the signal magnetic field 40. The busbar 10 corresponds to the configuration of FIGS. 6 and 7, including the first, second and third notches 51-53. The first and second magnetic sensors 21, 22 comprises a TMR element. As can be seen from FIGS. 8 and 9, the output signal Vₒᵤₜ varies linearly with the signal current 30 and signal magnetic field 40. FIG. 9 further reports the “common mode field”, i.e., the measured output signal Vₒᵤₜ as a function of an external uniform magnetic field 70. As expected, the measured output signal Vₒᵤₜ remains constant when the external uniform magnetic field 70 is varied (between −5 and 5 mT). In this configuration, the current measurement system 1 has −46 dB (˜99.5%) rejection of common mode field.
1 current measurement system
10 electrically conductive strip, busbar
11 first zone
12 second zone
14 first sub-strip
15 second sub-strip
101 first lateral side of the busbar
102 second lateral side of the busbar
2 TMR element
21 first magnetic sensor
22 second magnetic sensor
23 processing device
210 sense layer
211 sense magnetization
220 tunnel barrier layer
230 reference layer
231 reference magnetization
30 signal current
31 first current portion
32 second current portion
40 signal magnetic field
41 first signal magnetic field
42 second signal magnetic field
51 first notch
52 second notch
53 third notch
511 first edge
512 second edge
60 PCB
61 top PCB layer
62 inner PCB layer
70 external uniform magnetic field
Vₒᵤₜ output signal
V_{out,1} first output signal
V_{out,2} second output signal

1. A current measurement system, comprising:
an electrically conductive strip extending along a first direction and configured to pass a signal current to be measured along the first direction;
a first magnetic sensor and a second magnetic sensor, wherein each magnetic sensor is configured to output an output signal according to a signal magnetic field that is generated by the signal current;
wherein the strip comprises a first notch, extending from a first lateral side of the strip, along a second direction substantially perpendicular to the first direction and forming a first edge and a second edge on each side of the first notch along the second direction;
such that, in a first zone of the strip bordering the first edge, the signal current comprises a first current portion flowing substantially in the second direction and generates a first signal magnetic field with a first polarity;
and in a second zone of the strip bordering the second edge, the signal current comprises a second current portion flowing substantially in the second direction and generating a second signal magnetic field with a second polarity opposed to the first polarity;
wherein the first magnetic sensor is arranged in the first zone to outputs a first output signal according to the first signal magnetic field, and the second magnetic sensor is arranged in the second zone to outputs a second output signal according to the second signal magnetic field, the output signal corresponding to the difference between the first and the second output signals.

2. The current measurement system according to claim 1, wherein the strip further comprises a second notch and a third notch, both extending from a second side of the strip, opposed to the first side, such that the first zone comprises a first sub-strip and the second zone comprises a first sub-strip, each of the first and second sub-strips extending along the second direction on each side the first notch along the first direction.

3. The current measurement system according to claim 2, wherein each of the first and second magnetic sensors comprises at least one tunnel magnetoresistive (TMR) element.

4. The current measurement system according to claim 3, wherein each of the first and second magnetic sensors comprises four TMR elements arranged in a Wheatstone bridge circuit.

5. The current measurement system according to claim 1, further comprising a processing module configured to configured to subtract the first output signal outputted by the first magnetic sensor and the second output signal outputted by the second magnetic sensor.

6. The current measurement system according to claim 1, wherein the magnetic sensors are mounted on a PCB.
